(19) United States
(12) Patent Application Publication
(10) Pub. No.: US 2020/0266822 A1
(43) Pub. Date: Aug. 20, 2020

(54) LOGIC INTEGRATED CIRCUIT

(71) Applicant: NEC Corporation, Minato-ku, Tokyo (JP)

(72) Inventors: Yukihide TSUJI, Tokyo (JP); Toshitsugu SAKAMOTO, Tokyo (JP); Makoto MIYAMURA, Tokyo (JP); Ryusuke NEBASHI, Tokyo (JP); Ayuka TADA, Tokyo (JP); Xu BAI, Tokyo (JP)

(73) Assignee: NEC Corporation, Minato-ku, Tokyo (JP)

(21) Appl. No.: 16/648,820

(22) PCT Filed: Sep. 14, 2018
(86) PCT No.: PCT/JP2018/034150

§ 371 Date: Mar. 19, 2020

(30) Foreign Application Priority Data
Sep. 22, 2017 (JP) 2017-182658

(51) Int. Cl. H03K 19/185; H03K 19/173; H03K 19/17704; G11C 13/00; H01L 27/24; H01L 45/00; H03K 19/17728; H03K 19/17756; G06F 7/57

(52) U.S. Cl. CPC H03K 19/185; H03K 19/1737; H03K 19/17704; G11C 13/0069; H01L 27/2436; G11C 2013/009; H03K 19/17728; H03K 19/17756; H01L 27/2463; H01L 45/1233; G06F 7/57; H01L 45/085

(57) ABSTRACT

This logic integrated circuit has a plurality of first switch cells including variable resistance elements and a plurality of second switch cells including variable resistance elements. The logic integrated circuit comprises: a first output port and a second output port; the plurality of first switch cells for switching the electrical connections between a first wire and a third wire; the plurality of second switch cells for switching the electrical connections between a second wire and the third wire; a first control transistor which is connected to the first wire and which is for switching the electrical connections between the first wire and a first power line supplying power to the first wire; and a second control transistor which is connected to the second wire and which is for switching the electrical connections between the second wire and the first power line supplying power to the second wire.

### TECHNICAL FIELD

The present invention relates to a logic integrated circuit in which a logic circuit is reconfigurable, and particularly relates to a technique for reduced power consumption and increased integration of a logic integrated circuit.

### BACKGROUND ART

A programmable logic integrated circuit in which a logic circuit is reconfigurable is also referred to as a reconfigurable circuit, and can reconfigure various logic circuits by rewriting internal setting information. FIG. 1 is a circuit diagram of a general reconfigurable circuit. The reconfigurable circuit in FIG. 1 includes a plurality of logic blocks (LBs) 1001 and a plurality of routing blocks (RBs) 1002. The LB includes a lookup table (LUT) and a flip-flop (FF) such as a D-type flip-flop (DFF). The RB performs switching of an input-output signal to the LB and switching of a signal path between the LBs.

The number of configurable logics (circuit scale of a reconfigurable circuit) can be adjusted by designing a logic block (configurable logic block (CLB)) including an LB and an RB of a certain scale. Then, by adjusting the number of CLBs to be arranged in such a way as to be connected to one another, a semiconductor chip including a reconfigurable circuit of a different circuit scale according to customer needs can be manufactured. The reconfigurable circuit is currently used widely in a field such as generation of a prototype, image processing, and communication.

The RB being a switching unit of a signal is mounted by using a static random access memory (SRAM) switch constituted of an SRAM and a pass transistor. In recent years, as indicated in Patent Literature 1 (PTL1) and Patent Literature 2 (PTL2), a technique capable of reducing a chip area and power consumption by replacement with a resistance change element is proposed. As illustrated in FIG. 2(a), the resistance change element described above has a structure including a resistance change element (RE) constituted of a solid electrolyte material (IC) containing a metal ion between a first wiring layer (T1) and a second wiring layer (T2) formed above T1. FIG. 2(b) illustrates a symbolic expression of the resistance change element (RE) in FIG. 2(a). The resistance change element (RE) in FIGS. 2(a) and 2(b) can change a resistance value either from a high resistance state to a low resistance state or from a low resistance state to a high resistance state, by applying a forward bias voltage or a reverse bias voltage to both ends (T1 and T2) of the resistance change element, as illustrated in FIG. 2(c). A ratio of the low resistance state (on state) to the high resistance state (off state) of the resistance change element (RE) is 10⁵ or greater.

When a resistance change element is used as a switch on the reconfigurable circuit, a voltage is always applied to all the switches on the circuit. For this reason, higher reliability is required than that in a case of a memory switch to which a current and a voltage are applied only during an operation of reading data. Thus, instead of a switch cell having a 1T1R structure in which one resistance change element and one transistor are combined as a set, a complementary (1T2R) structure using one transistor and a pair of resistance change elements as illustrated in FIG. 3 is proposed (Patent Literature 3 (PTL3) and Patent Literature 4 (PTL4)).

FIG. 3(a) is a configuration diagram of a switch cell constituted of two resistance change elements and a transistor. FIG. 3(b) is a circuit diagram of a switch cell disposed as a cross point cell for signal switching. FIG. 3(c) is a perspective view and a plan view illustrating a wiring layout of the switch cell including the resistance change elements. The switch cell in FIG. 3(a) is constituted of two resistance change elements (RE[1] and RE[2]) and one transistor (Tr.). Electrodes on one side of the two resistance change elements (RE[1] and RE[2]) are connected to each other, and one of diffusion layers (source or drain) of the selection transistor (Tr.) is connected to a common node of the electrodes. The resistance change element (RE) is a resistance change element using a movement of a metal ion and an electrochemical reaction in a solid (ion conductor) in which an ion can freely move by application of an electric field or the like. The resistance change element (RE) is used as a switch element having a great resistance change amount and being capable of distinguishing whether a signal passes between electrodes or not. As illustrated in FIG. 2(a), the resistance change element (RE) described above is constituted of the ion conductive layer (IC), and the electrode (T1) and the electrode (T2) that are provided on the counter surfaces in contact with the ion conductive layer (IC). A metal ion is supplied from the electrode (T1) to the ion conductive layer, and a metal ion is not supplied from the electrode (T2). A resistance value of the ion conductor is changed by changing an applied voltage polarity, and a conductive state between the two electrodes is controlled.

The switch cell in a crossbar switch is disposed near each cross point of a wire (RV[j]) in a vertical direction and a wire (RH[k]) in a horizontal direction. Further, when the resistance change element near a certain cross point is turned on/off, two wires (SV[j] and GH[k]) for controlling the selection transistor (Tr.) are also connected in order to prevent false writing (disturbance) to the resistance change element being present near a different cross point. As illustrated in FIG. 3(b), at least four types of wires (RV, RH, SV, and GH) take a shape of running in the vertical or horizontal direction in a crossbar switch. FIGS. 3(a) and 3(b) can be constituted of a metal layer A, a metal layer B, a via, and the like illustrated in FIG. 3(c) in a switch cell region. The transistor (Tr.) in the switch cell is formed on a silicon substrate, and the resistance change elements (RE[1] and RE[2]) are formed in the wiring layers.

The switch cell using the resistance change element described above constitutes a crossbar switch, and is used as a switching switch (multiplexer) for signal input and signal switching of a routing block (RB). A switch cell array using such a resistance change element is proposed in Patent Literature 5 (PTL5).

### CITATION LIST

### Patent Literature

[PTL1] Japanese Patent No. 4356542

[PTL2] International Patent Publication No. WO2012/043502

[PTL3] International Patent Publication No. WO2013/190742

[PTL4] International Patent Publication No. WO2014/030393

[PTL5] International Patent Publication No. WO2016/042750

### Non Patent Literature

[NPL1] “Architecture of Reconfigurable-Logic Cell Array with Atom Switch: Cluster Size & Routing Fabrics”, Xu Bai, et. al., Proceedings of the 2015 ACM/SIGDA International Symposium on Field-Programmable Gate Arrays, pp. 269, (2015).

### SUMMARY OF INVENTION

### Technical Problem

When a switch cell using a resistance change element constitutes a programmable logic integrated circuit, it is desired that a leakage current can be reduced while suppressing an increase in the number of connection wires and an area increase due to the increase in the number of connection wires.

An object of the present invention is to provide a logic integrated circuit capable of reducing a leakage current while suppressing an increase in the number of connection wires and an area increase due to the increase in the number of connection wires.

### Solution to Problem

To achieve the above-mentioned object, a logical operation circuit according to the present application that comprises a plurality of first switch cells each including a resistance change element and a plurality of second switch cells each including a resistance change element, the logical operation circuit comprises:

a first output port and a second output port;

a plurality of first wires disposed along a first direction and connected to the first output port;

a plurality of second wires disposed along the first direction and connected to the second output port;

a plurality of first writing control lines disposed along the first wire and the second wire;

a plurality of third wires disposed along a second direction;

a plurality of second writing control lines disposed along the third wire;

the plurality of first switch cells that are disposed at a place where the first wire and the third wire intersect each other, have one of diffusion layers being connected to the first writing control line, and another diffusion layer being connected to the second writing control line, and switch an electrical connection between the first wire and the third wire;

the plurality of second switch cells that are disposed at a place where the second wire and the third wire intersect each other, have one of diffusion layers being connected to the first writing control line, and another diffusion layer being connected to the second writing control line, and switch an electrical connection between the second wire and the third wire;

a first control transistor that is connected to the first wire, and switches an electrical connection between a first power source line supplying power to the first wire and the first wire;
a second control transistor that is connected to the second wire, and switches an electrical connection between the first power source line supplying power to the second wire and the second wire;

a third control transistor that is connected to the first writing control line, and switches an electrical connection between a second power source line supplying power to the first writing control line and the first writing control line; and a fourth control transistor that is connected to the third wire, and switches an electrical connection between a third power source line supplying power to the third wire and the third wire.

### Advantageous Effects of Invention

The present invention is able to provide a programmable logic integrated circuit capable of reducing a leakage current while suppressing an increase in the number of connection wires and an area increase due to the increase in the number of connection wires.

### BRIEF DESCRIPTION OF DRAWINGS

FIG. 1 is a block diagram illustrating a reconfigurable circuit including a plurality of logic blocks and a plurality of routing blocks.

FIG. 2 (a) is a configuration diagram of a resistance change element, (b) is a symbolic expression of the resistance change element in (a), and (c) is a state table illustrating an applied voltage for changing a resistance of the resistance change element and an operation method of a state change of a resistance value.

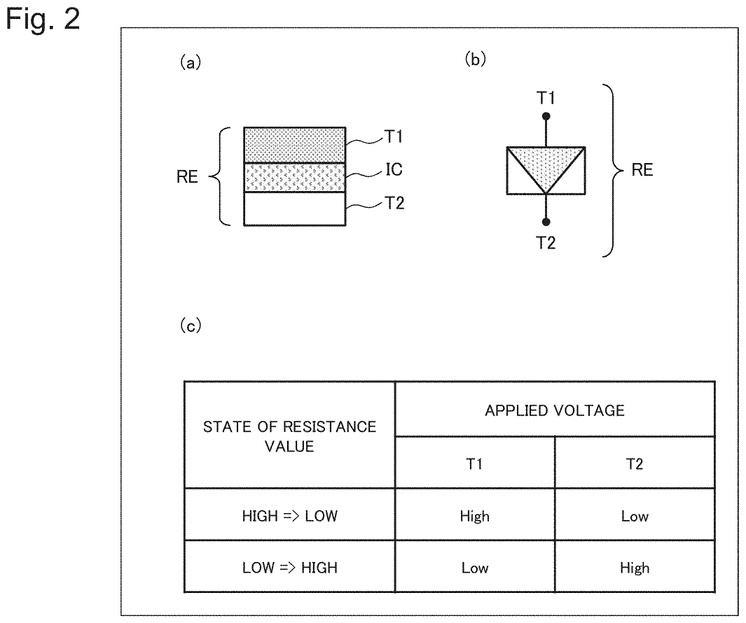

FIG. 3 (a) is a configuration diagram of a switch cell constituted of two resistance change elements and a transistor, (b) is a circuit diagram of a switch cell disposed as a cross point cell for signal switching, and (c) is a perspective view and a plan view illustrating a wiring layout of the switch cell including a resistance change element.

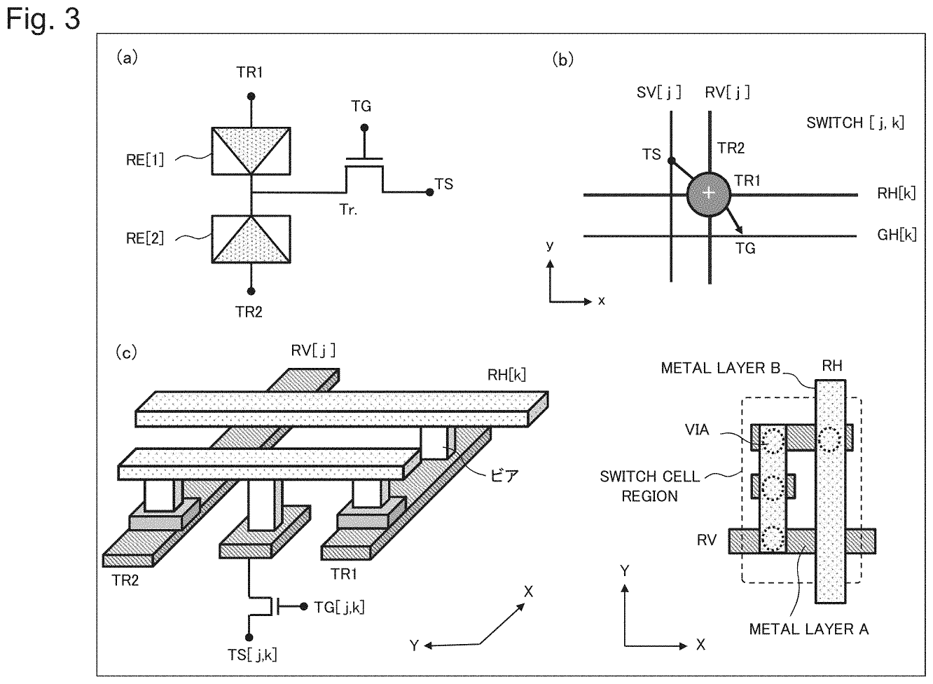

FIG. 4 is a block diagram illustrating a configuration example of a crossbar switch circuit including a switch cell array using a switch cell and an on/off switching control circuit of the switch cell.

FIG. 5 is a schematic diagram for describing an interface of the crossbar switch circuit in FIG. 4.

FIG. 6 is a schematic diagram for describing an interface of a crossbar switch circuit used as a memory for a lookup table.

FIG. 7 is a schematic diagram illustrating a configuration example (LUT architecture A) of an LUT using the crossbar switch circuit in FIG. 6.

FIG. 8 is a schematic diagram for describing an interface of a crossbar switch circuit used as a memory for a lookup table.

FIG. 9 is a schematic diagram illustrating a configuration example (LUT architecture B) of an LUT constituted by applying the crossbar switch circuit in FIG. 8.

FIG. 10A is a block diagram for describing a crossbar switch circuit used as a memory for a lookup table according to an example embodiment.

FIG. 10B is a schematic diagram for describing an interface of the crossbar switch circuit in FIG. 10A.

FIG. 11 (a) is a block diagram of a lookup table (LUT) constituted of a crossbar memory and a multiplexer (MUX), (b) is a block diagram of a reconfigurable circuit including a crossbar switch circuit, and (c) is a block diagram of an integrated circuit including a reconfigurable circuit according to the example embodiment, an arithmetic circuit, and the like.

FIG. 12 is a block diagram illustrating one example of the LUT using the crossbar switch circuit in FIG. 10B.

FIG. 13 is a table illustrating a comparison of the number of wires and a leakage current among the LUT using the crossbar switch circuit according to the example embodiment, the LUT architecture A, and the LUT architecture B.

FIG. 14 is a block diagram illustrating another example of multiplexers constituting an LUT according to an example embodiment.

FIG. 15 is a block diagram for describing an example of mounting M LUTs.

FIG. 16 is a block diagram for describing a mounting example of a setting data saving memory achieved by connecting an output port on a side that is not used as an LUT memory side of a crossbar switch circuit according to an example embodiment to an output port of a crossbar switch circuit being prepared separately.

FIG. 17 is a block diagram for describing a large-scale logic integrated circuit in which a writing control line in each crossbar is shared and redundant wiring is excluded while arranging CLBs including an LB and an RB on a tile.

### EXAMPLE EMBODIMENT

A problem to be solved by the present invention and a comparative example will be described prior to description of a specific example embodiment.

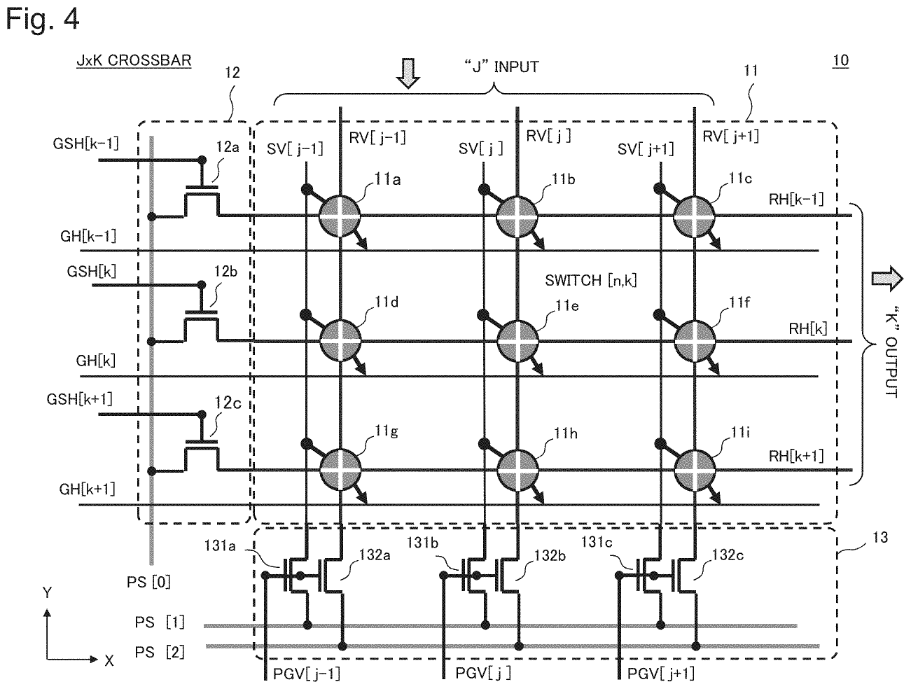

A crossbar switch circuit 10 in FIG. 4 is a reconfigurable circuit being an original form of a logic integrated circuit and a reconfigurable circuit according to an example embodiment of the present invention. The crossbar switch circuit 10 in FIG. 4 is a signal switching crossbar switch circuit of J inputs and K outputs (J and K: natural number). There is a case where the crossbar switch circuit of J inputs and K outputs is expressed as a J×K crossbar in the drawings. FIG. 4 also illustrates a control transistor and a control wire for controlling a supply voltage and a current source from a power source (PS) for writing when a resistance change element is rewritten (or written).

The crossbar switch circuit 10 in FIG. 4 includes a switch cell array 11, a vertical direction control circuit 12, and a horizontal direction control circuit 13. The vertical direction control circuit 12 includes first control transistors 12a to 12c. The horizontal direction control circuit 13 includes second control transistors 131a to 131c and third control transistors 132a to 132c. The switch cell array 11 includes a plurality of switch cells (switches [n, k]). FIG. 4 illustrates a state where switch cells 11a to 11i are arranged in a 3×3 array as one example of the plurality of switch cells (switches [n, k]). Each of the switch cells 11a to 11i includes a switch element. The switch cells 11a to 11c share a writing control line GH[k−1] and a signal line RH[k−1] being wires in an x direction. The writing control line GH[k−1] and the signal line RH[k−1] are wires independent of each other. The signal line RH[k−1] is connected to one of diffusion layers of the first control transistor 12a connected to the switch cells 11a to 11c. A power source line PS[0] is connected to the other diffusion layer of the first control transistor 12a. A writing control line GSH[k−1] is connected to a gate electrode of the first control transistor 12a. The writing control line GSH[k−1] is a wire used for changing a resistance of the switch element included in the switch cells 11a to 11c.

The switch cells 11d to 11f share a writing control line GH[k] and a signal line RH[k] being wires in the x direction. The writing control line GH[k] and the signal line RH[k] are wires independent of each other. The signal line RH[k] is connected to one of diffusion layers of the first control transistor 12b connected to the switch cells 11d to 11f. The power source line PS[0] is connected to the other diffusion layer of the first control transistor 12b. A writing control line GSH[k] is connected to a gate electrode of the first control transistor 12b. The writing control line GSH[k] is a wire used for changing a resistance of the switch element included in the switch cells 11d to 11f.

The switch cells 11g to 11i share a writing control line GH[k+1] and a signal line RH[k+1] being wires in the x direction. The writing control line GH[k+1] and the signal line RH[k+1] are wires independent of each other. The signal line RH[k+1] is connected to one of diffusion layers of the first control transistor 12c connected to the switch cells 11g to 11i. The power source line PS[0] is connected to the other diffusion layer of the first control transistor 12c. A writing control line GSH[k+1] is connected to a gate electrode of the first control transistor 12c. The writing control line GSH[k+1] is a wire used for changing a resistance of the switch element included in the switch cells 11g to 11i.

The switch cells 11a, 11d, and 11g share a writing control line SV[j−1] and a signal line RV[j−1] being wires in a y direction. The writing control line SV[j−1] and the signal line RV[j−1] are wires independent of each other. The writing control line SV[j−1] is connected to one of diffusion layers of the second control transistor 131a connected to the switch cells 11a, 11d, and 11g. A power source line PS[1] is connected to the other diffusion layer of the second control transistor 131a. A driver control line PGV[j−1] is connected to a gate electrode of the second control transistor 131a. Furthermore, the signal line RV[j−1] is connected to one of diffusion layers of the third control transistor 132a connected to the switch cells 11a, 11d, and 11g. A power source line PS[2] is connected to the other diffusion layer of the third control transistor 132a. The driver control line PGV[j−1] is connected to a gate electrode of the third control transistor 132a.

The switch cells 11b, 11e, and 11h share a writing control line SV[j] and a signal line RV[j] being wires in the y direction. The writing control line SV[j] and the signal line RV[j] are wires independent of each other. The writing control line SV[j] is connected to one of diffusion layers of the second control transistor 131b connected to the switch cells 11b, 11e, and 11h. The power source line PS[1] is connected to the other diffusion layer of the second control transistor 131b. A driver control line PGV[j] is connected to a gate electrode of the second control transistor 131b. Furthermore, the signal line RV[j] is connected to one of diffusion layers of the third control transistor 132b connected to the switch cells 11b, 11e, and 11h. The power source line PS[2] is connected to the other diffusion layer of the third control transistor 132b. The driver control line PGV[j] is connected to a gate electrode of the third control transistor 132b.

The switch cells 11c, 11f, and 11i share a writing control line SV[j+1] and a signal line RV[j+1] being wires in the y direction. The writing control line SV[j+1] and the signal line RV[j+1] are wires independent of each other. The writing control line SV[j+1] is connected to one of diffusion layers of the second control transistor 131c connected to the switch cells 11c, 11f, and 11i. The power source line PS[1] is connected to the other diffusion layer of the second control transistor 131c. A driver control line PGV[j+1] is connected to a gate electrode of the second control transistor 131c. Furthermore, the signal line RV[j+1] is connected to one of diffusion layers of the third control transistor 132c connected to the switch cells 11c, 11f, and 11i. The power source line PS[2] is connected to the other diffusion layer of the third control transistor 132c. The driver control line PGV[j+1] is connected to a gate electrode of the third control transistor 132c.

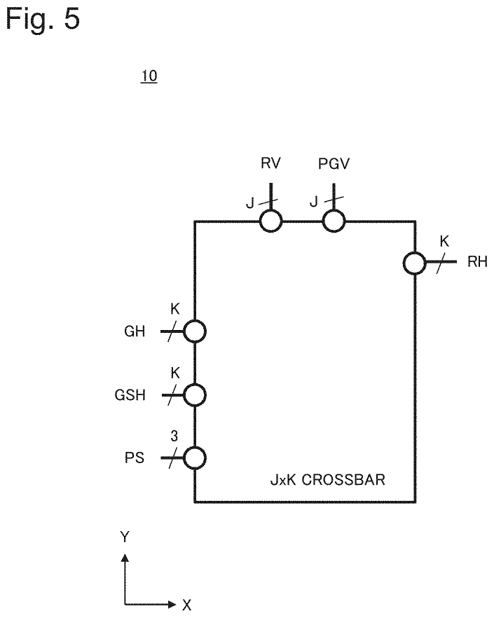

FIG. 5 is a schematic diagram illustrating an input-output interface with the crossbar switch circuit 10 (J×K crossbar) of J inputs and K outputs as one block. As in FIG. 5, the signal line RV and the driver control line PGV are disposed on one of sides corresponding to the x direction. Further, the writing control line GH, the writing control line GSH, and the power source line PS are arranged on one of sides corresponding to the y direction, and the signal line RH is disposed on the other side.

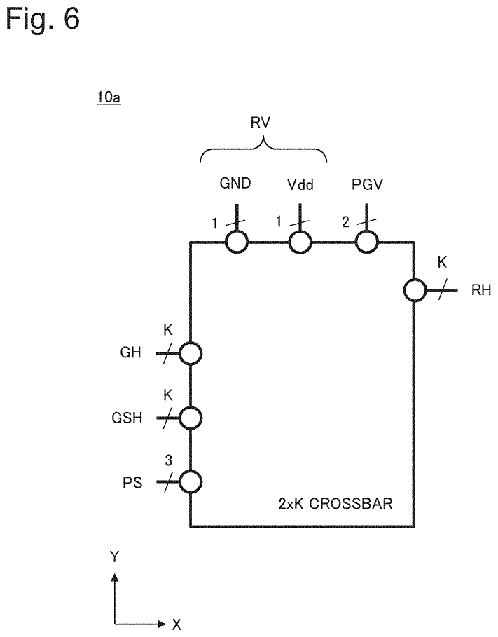

FIG. 6 is a schematic diagram illustrating an input-output interface with a crossbar switch circuit 10a (2×K crossbar) of 2 inputs and K outputs as one block. FIG. 6 is assumed to be a crossbar memory used in a lookup table (LUT). As in FIG. 6, a signal line RV to which each of a power source level (Vdd) and a ground level (GND) is input, and a driver control line PGV are disposed on one of sides corresponding to the x direction. Further, a writing control line GH, a writing control line GSH, and a power source line PS are arranged on one of sides corresponding to the y direction, and a signal line RH is disposed on the other side.

The crossbar switch circuit 10a can function as a memory when the power source level (Vdd) and the ground level (GND) are input to two RV ports of a crossbar switch configuration. An output level of an output node of the crossbar switch circuit 10a can be controlled to the Vdd or the GND when a switch cell at the Vdd or the GND is brought into an on state.

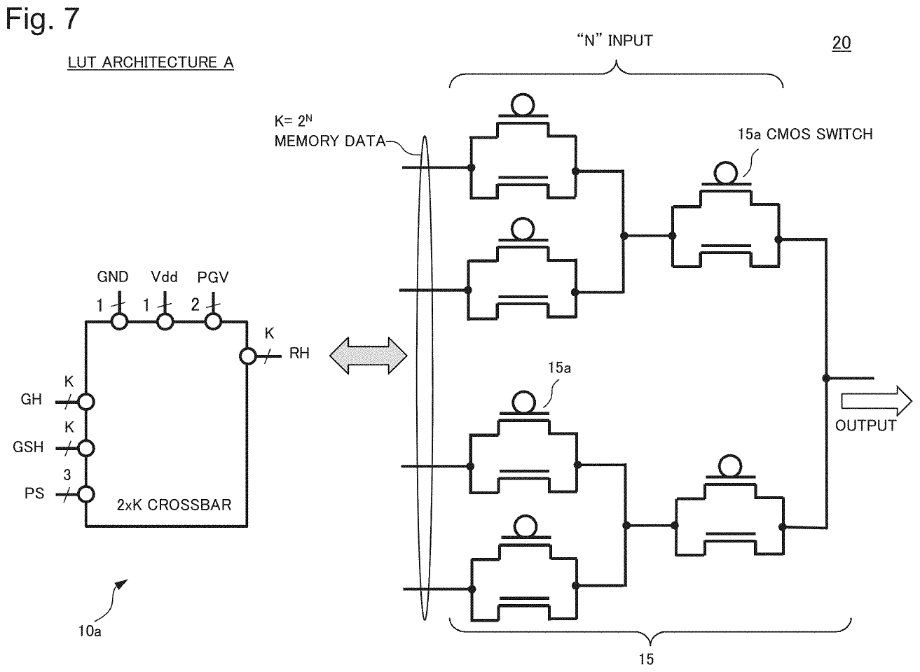

FIG. 7 is a schematic diagram illustrating a configuration example of an LUT 20 according to a comparative example. The configuration example illustrated in FIG. 7 is hereinafter referred to as an LUT architecture A. The LUT 20 in FIG. 7 is mounted in a state that an output from the crossbar switch circuit 10a (2×K crossbar) of 2 inputs and K outputs illustrated in FIG. 6 is connected to an input port of a multiplexer 15. In the example in FIG. 7, output nodes (K=N²) from the crossbar switch circuit 10a (2×K crossbar) of 2 inputs and K outputs are connected to N² input nodes of the multiplexer 15 of N inputs, and functions as one LUT 20 (herein, N and K are natural numbers).

The multiplexer 15 in FIG. 7 includes a configuration in which a plurality of complementary elements are combined. FIG. 7 illustrates an example of a complementary metal oxide semiconductor (CMOS) switch 15a in which a pair of a CMOS and an N-channel type metal oxide semiconductor (NMOS) being connected in parallel is combined. Note that FIG. 7 illustrates a configuration example for the two input LUT in which six switches are combined, but the number of the CMOS switches 15a and inputs are set in accordance with the scale of a logic circuit to be constituted. Note that, in FIG. 7 and subsequent drawings, a gate line connected to a gate electrode of an MOS switch such as a CMOS switch constituting a multiplexer is omitted.

A memory for a lookup table (LUT) in an LB can also be mounted by the same process without using another memory by using a resistance change switch cell (crossbar switch) used as a switch of an RB illustrated in FIGS. 6 and 7.

The number of wires constituting the crossbar switch circuit 10a (2×K crossbar) of 2 inputs and K outputs in FIG. 6, and the LUT 20 in FIG. 7 using the crossbar switch circuit 10a, and a leakage current will be examined in detail. In the crossbar switch configuration illustrated in FIG. 6, each of the power source level (Vdd) and the ground level (GND) is input to the two RV ports, and the output is connected to the memory input port in the LUT 20 as illustrated in FIG. 7. This mounting method (LUT architecture A) has an advantage that a wiring resource of only a minimum required number of 2^{N}=K connecting between the crossbar memory of the LUT and the multiplexer is needed. On the other hand, a potential difference of GND−Vdd is applied to the switch cell in an off state in each of 2^{N}=K lines. When an off resistance per switch cell is assumed to be 100 MΩ, a leakage of 10 nA×2^{N} at the Vdd=1 V occurs in one N input LUT.

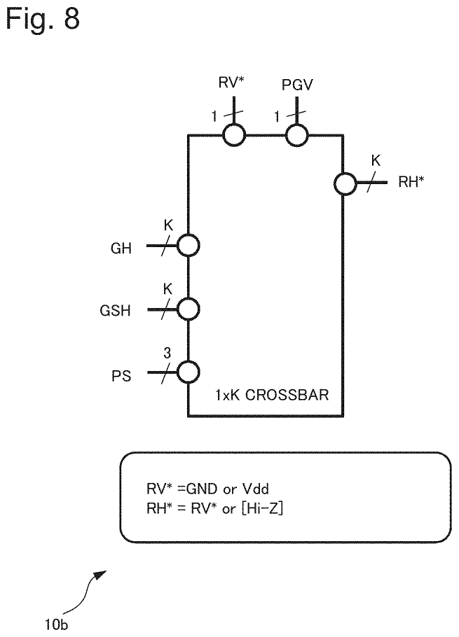

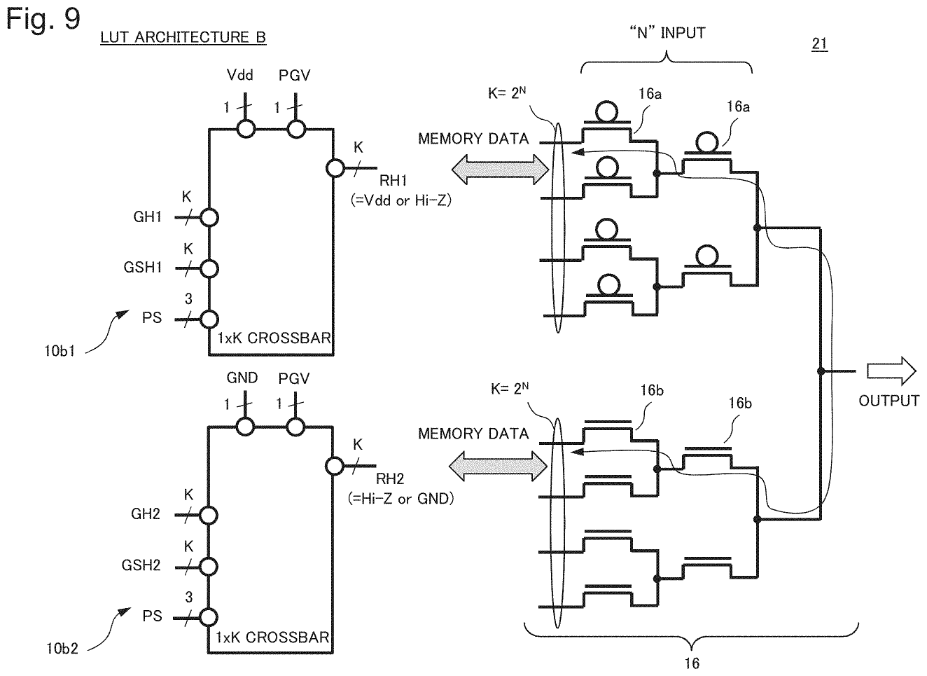

On the other hand, another mounting method is also conceivable. FIG. 9 is a schematic diagram illustrating another configuration example of an LUT according to a comparative example. The configuration example illustrated in FIG. 9 is hereinafter referred to as an LUT architecture B. FIG. 8 is a schematic diagram illustrating an input-output interface with a crossbar switch circuit (1×K crossbar) of 1 input and K outputs, which is a crossbar switch circuit 10b used in an LUT 21 illustrated in FIG. 9, as one block. As in FIG. 8, a signal line RV* to which each of a power source level (Vdd) and a ground level (GND) is input, and a driver control line PGV are disposed on one of sides corresponding to the x direction. Further, a writing control line GH, a writing control line GSH, and a power source line PS are arranged on one of sides corresponding to the y direction, and a signal line RH* is disposed on the other side. The signal line RV* or a high impedance state (Hi-Z) is provided to the signal line RH*.

A crossbar switch circuit 10b1 that inputs a power source level (Vdd) as the signal line RV* of the crossbar switch circuit 10b (1×K crossbar) of 1 input and K outputs in FIG. 8 and a crossbar switch circuit 10b2 that inputs a ground level (GND) as the signal line RV* are prepared. An output of the crossbar switch circuit 10b1 that inputs the power source level (Vdd) as the signal line RV* is connected to a memory input port of a multiplexer 16 constituted of a P-channel metal oxide semiconductor (PMOS) 16a illustrated in FIG. 9. An output of the crossbar switch circuit 10b2 that inputs the ground level (GND) as the signal line RV* is connected to a memory input port of the multiplexer 16 constituted of an NMOS 16b illustrated in FIG. 9. Then, as illustrated in FIG. 9, nodes being final output stages of the multiplexer 16 constituted of both the PMOS and the NMOS are connected to each other, thereby functioning as the LUT 21 in a complementary manner.

This mounting method (LUT architecture B) has a configuration in which an operating voltage (Vdd=1 V) is applied to only one switch cell in an off state. When an off resistance per switch cell is assumed to be 100 NM, a leakage current is 10 nA per LUT, which enables reducing a leakage current occurring in a resistance change element in an off state to ½^{N} in the LUT architecture B as compared to that in the LUT architecture A.

On the other hand, the LUT architecture B needs 2×2^{N}=2×K, which is twice that in the case of FIG. 6, of wiring resources connecting between the crossbar memory of the LUT and the multiplexer. Wires for writing to a switch cell, such as the writing control line GH and the writing control line GSH, also need to be doubled, and a wiring space of 2×3K needs to be secured in the horizontal direction. While a memory size is limited by a wiring space needed for writing and reading rather than a size of a resistance change element itself, there is a problem that an increase in the number of wires causes an increase in LUT size. Hereinafter, more specific example embodiments of the present invention will be described with reference to drawings.

### First Example Embodiment

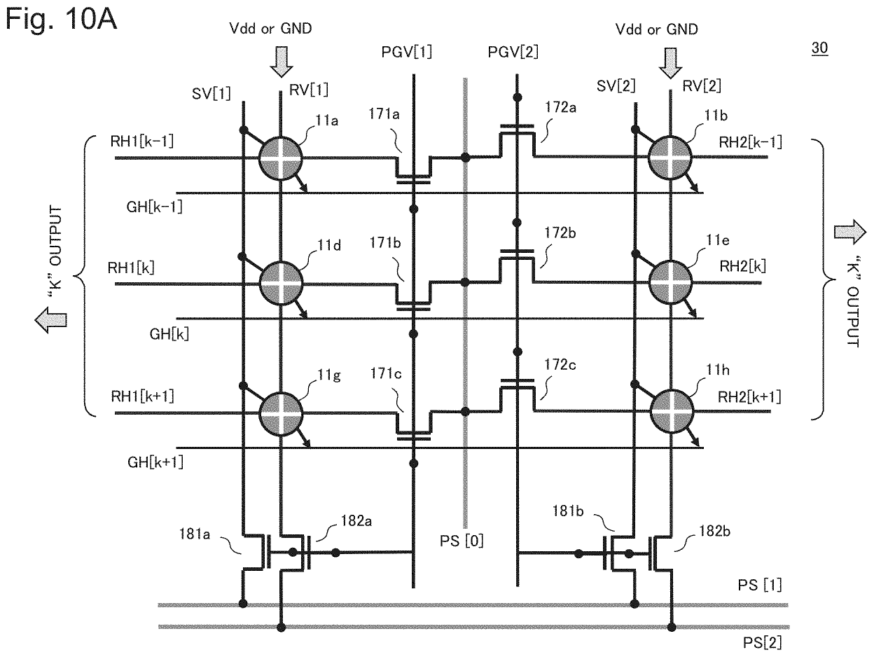

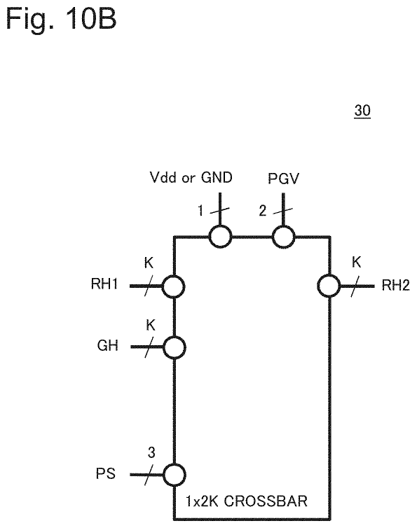

Next, a logic integrated circuit and a reconfigurable circuit according to a first example embodiment will be described. FIG. 10A is a block diagram for describing a crossbar switch circuit used as a memory for a lookup table (LUT) as one example of the logic integrated circuit and the reconfigurable circuit according to the present example embodiment. FIG. 10B is a schematic diagram for describing an interface of the crossbar switch circuit in FIG. 10A.

A crossbar switch circuit 30 in FIG. 10A includes switch cells 11a, 11d, and 11g as one example of a plurality of first switch cells including a resistance change element, and switch cells 11b, 11e, and 11h as one example of a plurality of second switch cells including a resistance change element. Furthermore, the crossbar switch circuit 30 in FIG. 10A includes control transistors 171a, 171b, and 171c as one example of first control transistors, and control transistors 172a, 172b, and 172c as one example of second control transistors. Furthermore, the crossbar switch circuit 30 in FIG. 10A includes control transistors 181a and 181b as one example of third control transistors, and control transistors 182a and 182b as one example of fourth control transistors. Note that the circuit configuration illustrated in FIG. 10A schematically illustrates a part of the configuration of the crossbar switch circuit 30, and does not represent the whole. Further, the number of elements and signal lines of the crossbar switch circuit 30 for achieving the reconfigurable circuit is not limited to those as illustrated in FIG. 10A.

The switch cells 11a and 11b share a writing control line GH[k−1] (also referred to as a first writing control line) being a wire in the x direction (also referred to as a first direction). A signal line RH1[k−1] is connected to one of diffusion layers of the control transistor 171a connected to the switch cell 11a. A signal line RH2[k−1] is connected to one of diffusion layers of the control transistor 172a connected to the switch cell 11b. A power source line PS[0] (also referred to as a first power source line) is connected to the other diffusion layer of the control transistor 171a and the control transistor 172a. A writing control line PGV[1] (also referred to as a second writing control line) is connected to a gate electrode of the control transistor 171a. A writing control line PGV[2] (also referred to as a third writing control line) is connected to a gate electrode of the control transistor 172a.

The switch cells 11d and 11e share a writing control line GH[k] being a wire in the x direction. A signal line RH1[k] is connected to one of diffusion layers of the control transistor 171b connected to the switch cell 11d. A signal line RH2[k] is connected to one of diffusion layers of the control transistor 172b connected to the switch cell 11e. The power source line PS[0] is connected to the other diffusion layer of the control transistor 171b and the control transistor 172b. The writing control line PGV[1] is connected to a gate electrode of the control transistor 171b. The writing control line PGV[2] is connected to a gate electrode of the control transistor 172b.

The switch cells 11g and 11h share a writing control line GH[k+1] being a wire in the x direction. A signal line RH1[k+1] is connected to one of diffusion layers of the control transistor 171c connected to the switch cell 11g. A signal line RH2[k+1] is connected to one of diffusion layers of the control transistor 172c connected to the switch cell 11h. The power source line PS[0] is connected to the other diffusion layer of the control transistor 171c and the control transistor 172c. The writing control line PGV[1] is connected to a gate electrode of the control transistor 171c. The writing control line PGV[2] is connected to a gate electrode of the control transistor 172c.

The switch cells 11a, 11d, and 11g share a writing control line SV[1] (also referred to as a second writing control line) and a signal line RV[1] being a wire in the y direction (also referred to as a second direction). The writing control line SV[1] is connected to one of diffusion layers of the control transistor 181a connected to the switch cells 11a, 11d, and 11g. A power source line PS[1] (also referred to as a second power source line) is connected to the other diffusion layer of the control transistor 181a. The signal line RV[1] is connected to one of diffusion layers of the control transistor 182a connected to the switch cells 11a, 11d, and 11g. A power source line PS[2] (also referred to as a third power source line) is connected to the other diffusion layer of the control transistor 182a.

The switch cells 11b, 11e, and 11h share a writing control line SV[2] and a signal line RV[2] being wires in the y direction. The writing control line SV[2] is connected to one of diffusion layers of the control transistor 181b connected to the switch cells 11b, 11e, and 11h. The power source line PS[1] is connected to the other diffusion layer of the control transistor 181b. The signal line RV[2] is connected to one of diffusion layers of the control transistor 182b connected to the switch cells 11b, 11e, and 11h. The power source line PS[2] (also referred to as a third power source line) is connected to the other diffusion layer of the control transistor 182b.

FIG. 10B is a schematic diagram illustrating an input-output interface with the crossbar switch circuit 30 (1×2K crossbar) of 1 input and 2K outputs as one block. FIG. 10B is assumed to be a crossbar memory used in a lookup table. As in FIG. 10B, a signal line RV to which a power source level (Vdd) or a ground level (GND) is input and a driver control line PGV are disposed on one of sides corresponding to the x direction. Further, a signal line RH1, a writing control line GH, and a power source line PS are arranged on one of sides corresponding to the y direction, and a signal line RH2 is disposed on the other side. Note that the schematic diagram of the crossbar switch circuit 10 illustrated in FIG. 10B illustrates one example, and is not limited thereto.

In the crossbar switch circuit 30 in FIGS. 10A and 10B, output ports of a crossbar switch as one example of a first output port and a second output port are provided on left and right boundary portions of the crossbar switch. For example, the signal line RH1[k−1], the signal line RH[k], and the signal line RH1[k+1] are connected to the first output port, and the signal line RH2[k−1], the signal line RH2[k], and the signal line RH2[k+1] are connected to the second output port.

The power source line PS[0] for writing that runs in the vertical direction in FIG. 10A is a power source shared by the switch cells 11a, 11d, and 11g provided on the left side of the power source line PS[0] and the switch cells 11b, 11e, and 11h provided on the right side of the power source line PS[0].

In FIG. 10A, gate lines of the control transistors 171a, 171b, and 171c, that are provided between the power source line PS[0] and the output port and are arranged in the vertical direction, are shared. Furthermore, a gate line of the control transistor 181a that controls a power source line for writing from the power source line PS[1] and a gate line of the control transistor 182a that controls a power source line for writing from the power source line PS[2] are also shared. Further, in FIG. 10A, gate lines of the control transistors 172a, 172b, and 172c, that are provided between the power source line PS[0] and the output port and are arranged in the vertical direction, are shared. Furthermore, a gate line of the control transistor 181b that controls a power source line for writing from the power source line PS[1] and a gate line of the control transistor 182b that controls a power source line for writing from the power source line PS[2] are also shared. Note that it is desired that a gate line of a control transistor is shared in order to reduce the number of wires, but the present example embodiment is not necessarily limited to this.

In the crossbar switch circuit 30 in FIGS. 10A and 10B, either one of the power source level (Vdd) and the ground level (GND) is assumed to be an input to the crossbar switch. When the input is the power source level (Vdd), the output from the crossbar switch circuit 30 is controlled in such a way as to be set to either the Vdd or a high resistance state (high impedance state: Hi-Z). When the input is the ground level (GND), the output from the crossbar switch circuit 30 is controlled controls in such a way as to be set to either the GND or the high resistance state (high impedance state: Hi-Z).

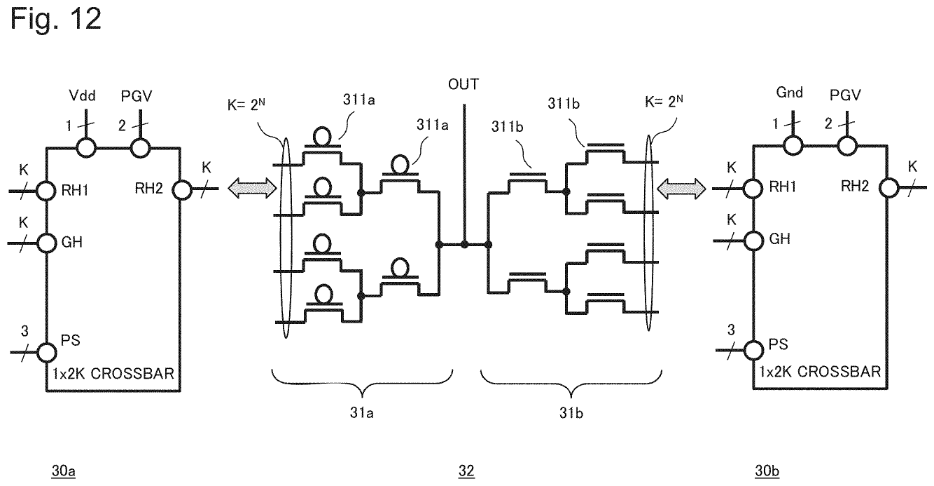

A lookup table 32 (LUT 32) in FIG. 12 includes a crossbar switch circuit 30a being one embodiment of the crossbar switch circuit 30 in FIG. 10B, a multiplexer 31a constituted of a plurality of PMOS switches 311a, a multiplexer 31b constituted of a plurality of NMOS switches 311b, and a crossbar switch circuit 30b being one embodiment of the crossbar switch circuit 30 in FIG. 10B.

The multiplexer 31a is constituted of the plurality of PMOS switches 311a, and FIG. 12 illustrates a case where the multiplexer 31a is constituted of six PMOS switches 311a. The multiplexer 31a selects data from among K=2^{N} pieces of data from the crossbar switch circuit 30a according to an input signal to the LUT 32, and outputs the data. The multiplexer 31b is constituted of the plurality of NMOS switches 311b, and FIG. 12 illustrates a case where the multiplexer 31b is constituted of six NMOS switches 311b. The multiplexer 31b selects data from among K=2^{N} pieces of data from the crossbar switch circuit 30b according to an input signal to the LUT 32, and outputs the data. In FIG. 12, an output node OUT is constituted in a state that the PMOS switches 311a being output stages of the multiplexer 31a and the NMOS switches 311b being output stages of the multiplexer 31b are connected.

As illustrated in FIG. 12, the lookup table 32 (LUT 32) includes input ports disposed separately on each of the PMOS and the NMOS on the left and the right. The input of the multiplexer 31a in FIG. 12 is connected to the output port of the crossbar switch circuit 30a disposed on the left side of the input. The input of the multiplexer 31b in FIG. 12 is connected to the output port of the crossbar switch circuit 30b disposed on the right side of the input. An input signal to a gate of the PMOS switch 311a of the multiplexer 31a in the LUT 32 is associated with an input signal to a gate of the NMOS switch 311b of the multiplexer 31b, and one conduction path is selected from each of the left and the right for the gate input signal set to the LUT 32.

When a switch cell connected to a source on the PMOS side in two crossbars connected to both ends of one conduction path is brought into an on state, and a Vdd is output, a switch cell in a crossbar connected to a drain on the opposite NMOS side is brought into an off state, and a high resistance state (high impedance state: Hi-Z) is output.

In this way, a Vdd level can be output in the output node OUT in which the source and the drain of the PMOS switch 311a being a final stage of the multiplexer 31a in the LUT 32 and the NMOS switch 311b being a final stage of the multiplexer 31b are connected to each other.

In contrast, when the switch cell in the crossbar switch connected to the source on the PMOS switch 311a side is brought into an off state, and the high impedance state (Hi-Z) is output, the switch cell in the crossbar switch connected to the drain on the NMOS switch 311b side on the opposite side is brought into an on state, and a GND is output. In this way, a GND level can be output in the output node OUT in which the source and the drain of the NMOS switch 311b and the PMOS switch 311a in the LUT 32 are connected to each other.

In this way, a desired logical operation can be performed as the LUT 32 when one rewrites a switch cell on a path selected for each gate input signal set to the LUT 32 with paying attention to the complementarity described above.

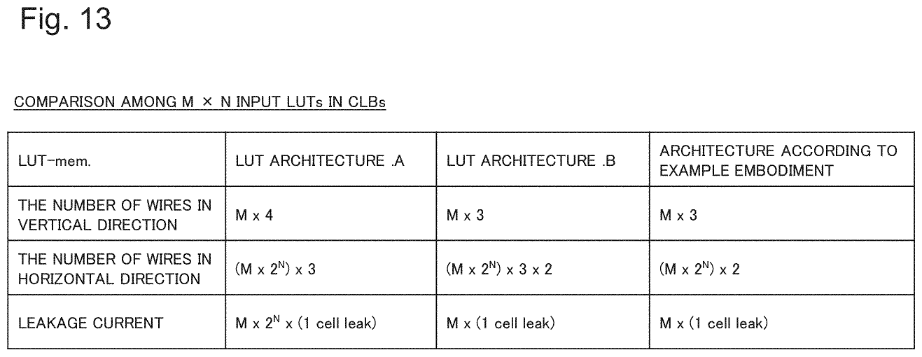

FIG. 13 is a table illustrating a comparison of the number of wires and a leakage current among the LUT using the crossbar switch circuit according to the architecture of the present example embodiment, the LUT architecture A described above, and the LUT architecture B described above. Particularly, the table gives a comparison of the number of wires needed in vertical and horizontal directions including a signal line and a writing line of M N-input LUTs in a CLB, and a leakage current due to a resistance change element in an off state. In a case of the present example embodiment, an operating voltage is applied to only one switch cell in the off state, and thus the leakage current can be reduced to ½^{N} as compared to that in the LUT architecture A. Further, the output node from each crossbar switch for the LUT memory can be input to each adjacent LUT in addition to being capable of reducing the number of wires related to the Vdd and the GND, and thus signal lines do not uselessly run in parallel. Thus, a wiring space to be secured for alleviating wiring congestion can be reduced, and a circuit area can also be reduced.

### Second Example Embodiment

Next, a logic integrated circuit and a reconfigurable circuit according to a second example embodiment will be described. In the first example embodiment, the crossbar switch circuit used as the memory for the lookup table (LUT) is described as one example of the logic integrated circuit and the reconfigurable circuit. However, the present invention is not limited to the logic integrated circuit and the reconfigurable circuit in the first example embodiment having the configuration described above. For example, the multiplexers 31a and 31b constituting the LUT 32 according to the example embodiment illustrated in FIG. 12 are not limited to this.

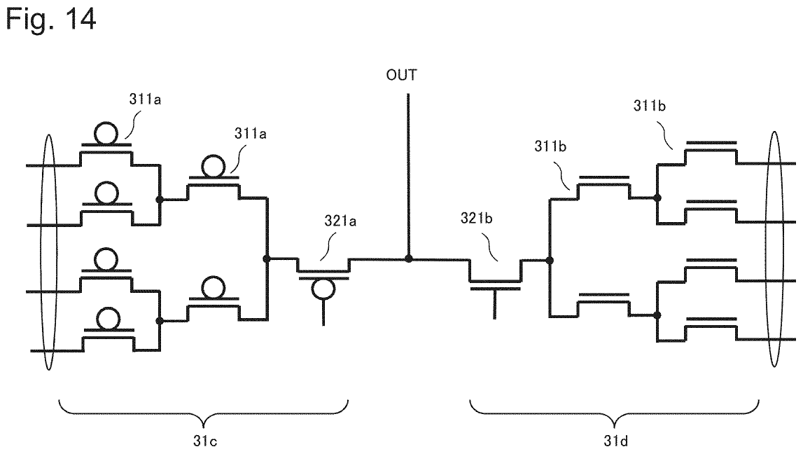

FIG. 14 is a block diagram illustrating another example of multiplexers constituting an LUT 32 according to the example embodiment. A PMOS switch and an NMOS switch are interposed between an output node OUT and a PMOS switch 311a, and between the output node OUT and an NMOS switch 311b, respectively, with respect to the output node OUT to which a source and a drain of the PMOS switch 311a and the NMOS switch 311b in FIG. 12 are connected to each other. As illustrated in FIG. 14, a multiplexer 31c includes a plurality of PMOS switches 311a, and, furthermore, one PMOS switch 321a is connected between the PMOS switch 311a and the output node OUT. A multiplexer 31d includes a plurality of NMOS switches 311b, and, furthermore, one PMOS switch 321b is connected between the NMOS switch 311b and the output node OUT.

In a case of the LUT 32 constituted of the multiplexers 31c and 31d illustrated in FIG. 14, a writing voltage and a writing current can be prevented from flowing between different crossbar switch circuits via a signal transmission path of a lookup table when two gate voltages of the PMOS switch 321a and the NMOS 321b described above during writing of a switch cell is controlled. In other words, interference of a current and a voltage between crossbars when a switch cell in a crossbar switch is written can be suppressed.

### Third Example Embodiment

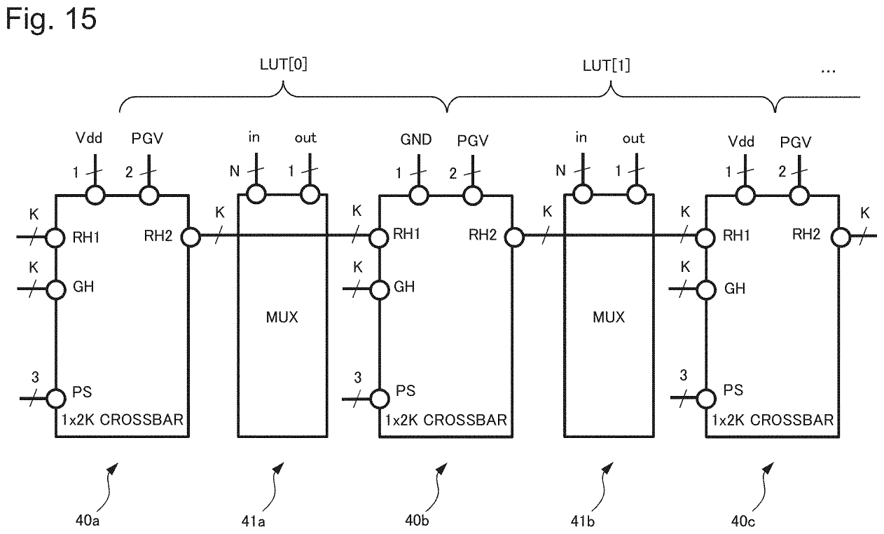

Next, a logic integrated circuit and a reconfigurable circuit according to a third example embodiment will be described. In the first example embodiment, the crossbar switch circuit used as the memory for the lookup table (LUT) is described as one example of the logic integrated circuit and the reconfigurable circuit. The present example embodiment is an application example using the crossbar switch circuit according to the first example embodiment. FIG. 15 is a block diagram for describing an example of mounting M LUTs. The plurality of LUTs according to the first example embodiment are conceivably disposed adjacent to each other. FIG. 15 illustrates an example of a logic integrated circuit and a reconfigurable circuit in which the M LUTs (LUT[0], LUT[1], . . . ) are cascade-connected.

The logic integrated circuit and the reconfigurable circuit in FIG. 15 include crossbar switch circuits 40a, 40b, and 40c being one embodiment of the crossbar switch circuit 30 (1×2K crossbar) of 1 input and 2K outputs according to the first example embodiment described above, and multiplexers 41a and 41b (MUXs 41a and 41b) disposed between the crossbar switch circuits. A Vdd is provided to a signal line RV in the crossbar switch circuits 40a and 40c. A GND is provided to a signal line RV in the crossbar switch circuit 40b.

The multiplexer 41a selects an output from a second output port of the crossbar switch circuit 40a, and outputs the output. The multiplexer 41b selects an output from a second output port of the crossbar switch circuit 40b, and outputs the output. The LUT[0] is constituted of the crossbar switch circuit 40a and the multiplexer 41a. The LUT[1] is constituted of the crossbar switch circuit 40a and the multiplexer 41a.

### Fourth Example Embodiment

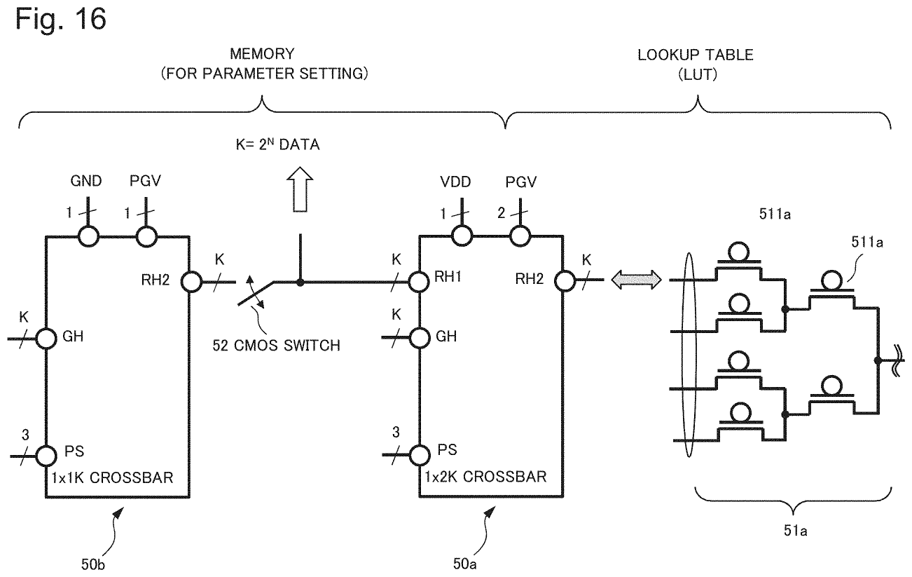

Next, a logic integrated circuit and a reconfigurable circuit according to a fourth example embodiment will be described. In the first example embodiment, the crossbar switch circuit used as the memory for the lookup table (LUT) is described as one example of the logic integrated circuit and the reconfigurable circuit. The present example embodiment is an application example using the crossbar switch circuit according to the first example embodiment. FIG. 16 illustrates that an output port on a side that is not used as an LUT memory side of a crossbar switch circuit according to the example embodiment is connected to an output port of a crossbar switch circuit being prepared separately.

A logic integrated circuit and a reconfigurable circuit in FIG. 16 include a crossbar switch circuit 50a being one embodiment of the crossbar switch circuit 30 (1×2K crossbar) of 1 input and 2K outputs according to the first example embodiment described above, and a multiplexer 51a constituted of a plurality of PMOS switches 511a. Furthermore, the logic integrated circuit and the reconfigurable circuit in FIG. 16 include a CMOS switch 52 and a crossbar switch circuit 50b (1×1K crossbar) of 1 input and 1K outputs. The crossbar switch circuit 50a outputs K pieces of data from a second output port, and the multiplexer 51a selects and outputs the K pieces of data, thereby constituting a lookup table (LUT). A Vdd is provided to a signal line RV in the crossbar switch circuit 50a. A GND is provided to a signal line RV in the crossbar switch circuit 50b.

The present example embodiment makes use of a first output port that is not used as a crossbar memory of the LUT and is different from the second output port which constitutes a part of the LUT of the crossbar switch circuit 50a. In this way, a memory circuit for parameter setting can be constituted by connecting the output port of the crossbar switch circuit 50b being prepared separately and the first output port of the crossbar switch circuit 50a to each other via the CMOS switch 52. Such a configuration can make effective use of the unused output port (first output port) of the crossbar switch circuit 40a present at the end as in FIG. 15.

### Fifth Example Embodiment

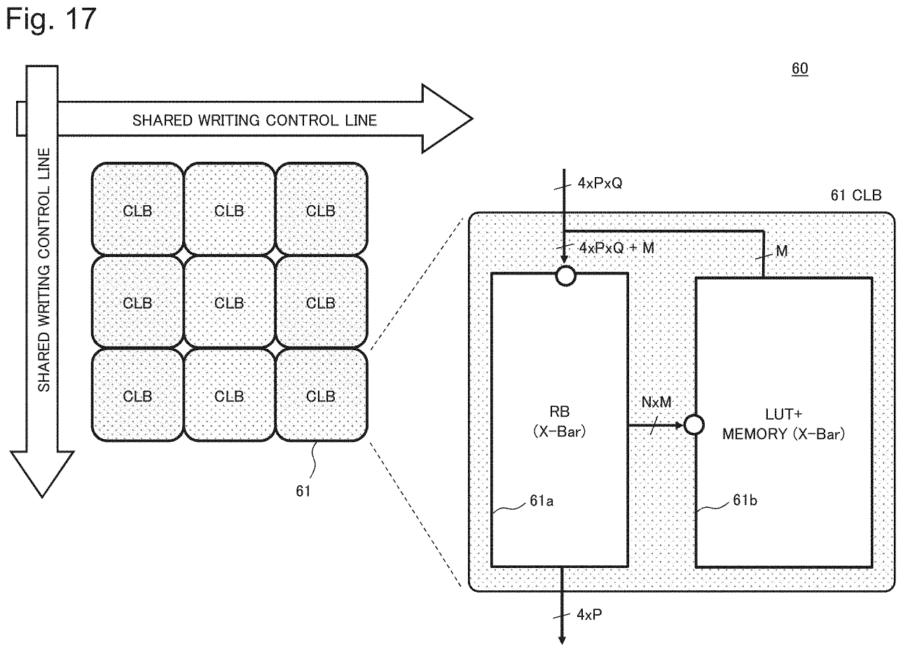

Next, an integrated circuit including a logic integrated circuit and a reconfigurable circuit according to a fifth example embodiment will be described. FIG. 17 is a block diagram illustrating a large-scale logic integrated circuit that shares a writing control line in each crossbar and excludes redundant wiring while arranging reconfigurable circuits including an LB and an RB on a tile.

As illustrated in FIG. 17, an integrated circuit 60 with a larger scale can be constituted by arranging a plurality of reconfigurable circuits 61 (configurable logic blocks (CLBs)) and connecting the reconfigurable circuits 61 to each other. Each of the reconfigurable circuits 61 includes a routing block 61a (RB 61a) and a logic block 61b (LB 61b) including an LUT and a memory. The writing control line in each crossbar is shared while such reconfigurable circuits 61 are arranged on the tile.

### Other Example Embodiment

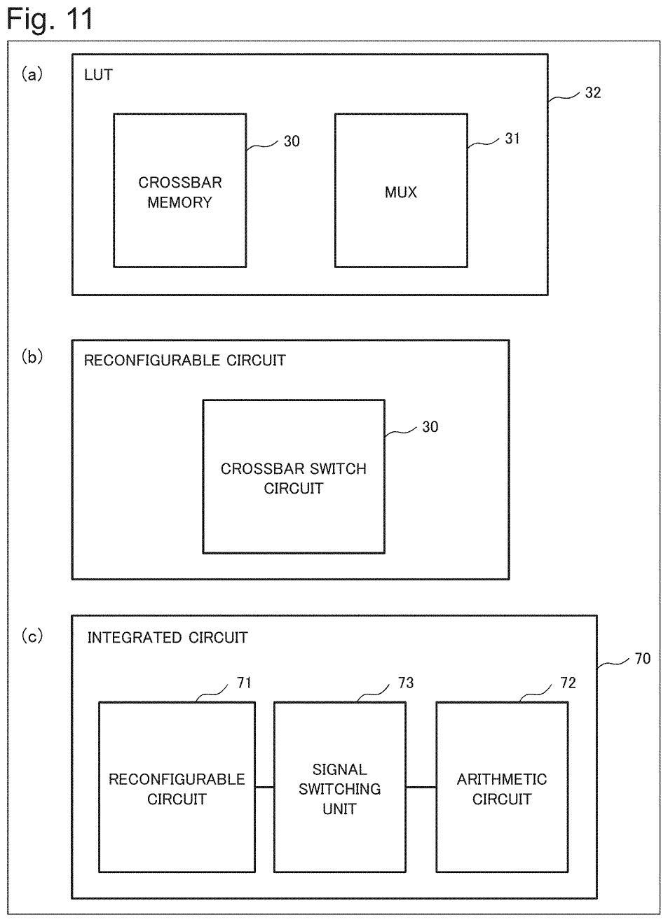

While the preferable example embodiments have been described above, the present invention is not limited to the example embodiments. As in FIG. 11(b), a reconfigurable circuit may include the crossbar switch circuit 30 as in FIG. 10A. It is also conceivable that, as in FIG. 11(c), an integrated circuit 70 includes a reconfigurable circuit 71 constituted from the example embodiments described above and an arithmetic circuit 72 that is not reconfigurable but enables a signal processing function, and the reconfigurable circuit 71 and the arithmetic circuit 72 are configured in such a way as to transmit and receive a signal to and from each other via a signal switching unit 73.

Further, a synchronous circuit such as a DFF may be present in a logic block (LB) of a reconfigurable circuit as necessary, and the setting memory described in the fourth example embodiment described above as synchronous and asynchronous selections of a signal may be used as an input signal to a selector.

An input-output signal between LBs may be connected via a routing block (RB) mounted by a crossbar as illustrated in FIG. 17. It is desired that the crossbar circuit illustrated in FIG. 4 mounts the RB described above with the same resistance change element. A reconfigurable circuit that can perform a larger-scale logical operation may be constructed by constructing a desired signal path. Note that a plurality of crossbars can improve efficiency of a control signal line by using a shared writing control line.

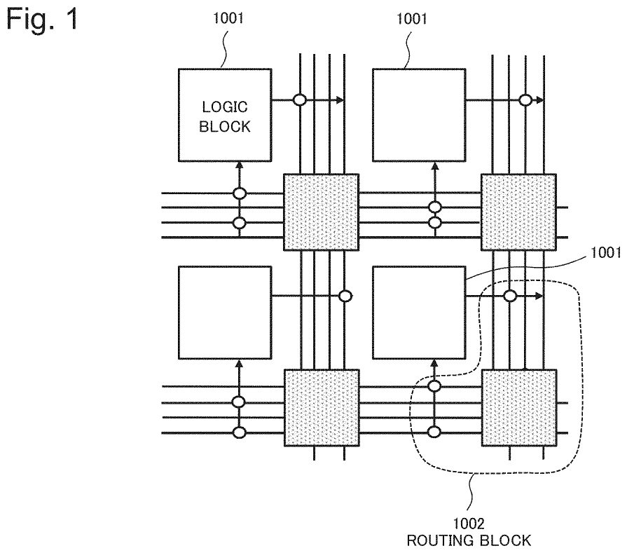

An input-output signal between LBs is connected via the routing block (RB) as illustrated in FIG. 1. A reconfigurable circuit that can perform a larger-scale logical operation can be constructed by constructing a desired signal path. The RB described above is mounted on the crossbar circuit using the same resistance change element. As illustrated in FIG. 17, when the CLBs constituted of a part of the LB and the RB are repeatedly arranged, the crossbar circuit is included in each of the CLBs, but a control signal line for writing of a switch cell in the crossbar circuit is shared among the CLBs.

As a resistance change element used for a switch cell, a resistance change element that has a resistance state being changed by application of a voltage equal to or greater than a certain value for a predetermined period of time or longer and being held, such as a resistance random access memory (ReRAM) using a transition-metal oxide and NanoBridge (Registered Trademark of NEC Corporation) using an ion conductor, may be used. Further, from a viewpoint of high disturb tolerance, it is desirable that a resistance change element is a bipolar-type resistance change element having polarity in an application direction of a voltage, and a configuration in which a bipolar-type resistance change elements are connected in series while opposing each other and a switch (transistor) is disposed at a connecting point of the two switches.

The whole or part of the example embodiments disclosed above can be described as, but not limited to, the following supplementary notes.

### (Supplementary Note 1)

A logical operation circuit that comprises a plurality of first switch cells each including a resistance change element and a plurality of second switch cells each including a resistance change element, the logical operation circuit comprising:

a first output port and a second output port;

a plurality of first wires disposed along a first direction and connected to the first output port;

a plurality of second wires disposed along the first direction and connected to the second output port;

a plurality of first writing control lines disposed along the first wire and the second wire;

a plurality of third wires disposed along a second direction;

a plurality of second writing control lines disposed along the third wire;

the plurality of first switch cells that are disposed at a place where the first wire and the third wire intersect each other, have one of diffusion layers being connected to the first writing control line, and another diffusion layer being connected to the second writing control line, and switch an electrical connection between the first wire and the third wire;

the plurality of second switch cells that are disposed at a place where the second wire and the third wire intersect each other, have one of diffusion layers being connected to the first writing control line, and another diffusion layer being connected to the second writing control line, and switch an electrical connection between the second wire and the third wire;

a first control transistor that is connected to the first wire, and switches an electrical connection between a first power source line supplying power to the first wire and the first wire;

a second control transistor that is connected to the second wire, and switches an electrical connection between the first power source line supplying power to the second wire and the second wire;

a third control transistor that is connected to the first writing control line, and switches an electrical connection between a second power source line supplying power to the first writing control line and the first writing control line; and a fourth control transistor that is connected to the third wire, and switches an electrical connection between a third power source line supplying power to the third wire and the third wire.

### (Supplementary Note 2)

The logical operation circuit according to supplementary note 1, wherein a plurality of the first control transistors are provided according to a number of the plurality of first wires, and a gate of the plurality of first control transistors is connected in a shared manner.

### (Supplementary Note 3)

The logical operation circuit according to supplementary note 1 or 2, wherein

a plurality of the second control transistors are provided according to a number of the plurality of second wires, and

a gate of the plurality of second control transistors is connected in a shared manner.

### (Supplementary Note 4)

The logical operation circuit according to any one of supplementary notes 1 to 3, wherein,

among a plurality of second writing control lines, a gate of a third control transistor connected to a second writing control line connected to the plurality of first switch cells and a gate of a fourth control transistor connected to a third wire connected to the plurality of first switch cells are connected to a gate of the plurality of first control transistors in a shared manner.

### (Supplementary Note 5)

The logical operation circuit according to any one of supplementary notes 1 to 4, wherein,

among a plurality of second writing control lines, a gate of a third control transistor connected to a second writing control line connected to the plurality of second switch cells and a gate of a fourth control transistor connected to a third wire connected to the plurality of second switch cells are connected to a gate of the plurality of second control transistors in a shared manner.

### (Supplementary Note 6)

A lookup table comprising:
a crossbar memory including the logical operation circuit according to any one of supplementary notes 1 to 5; and a multiplexer that selects and outputs an output from the first output port or the second output port of the crossbar memory.

### (Supplementary Note 7)

The lookup table according to supplementary note 6, further comprising:

a plurality of the logical operation circuits according to any one of supplementary notes 1 to 5;

a plurality of switches of a first conductive-type transistor being a plurality of switches that select an output from the first output port of one of the logical operation circuits;

a plurality of switches of a second conductive-type transistor being a plurality of switches that selects an output from the second output port of another of the logical operation circuits; and

an output node derived from a switch of an output stage of the plurality of switches of the first conductive-type transistor and a switch of an output stage of the plurality of switches of the second conductive-type transistor.

### (Supplementary Note 8)

The lookup table according to supplementary note 7, further comprising:

a switch of a first conductive-type transistor inserted between a switch of an output stage of the plurality of switches of the first conductive-type transistor and the output node; and

a switch of a second conductive-type transistor inserted between a switch of an output stage of the plurality of switches of the second conductive-type transistor and the output node.

### (Supplementary Note 9)

The lookup table according to any one of supplementary notes 6 to 8, wherein

the first output port or the second output port on a side that is not selected by the multiplexer that selects an output from the first output port or the second output port among the first output port and the second output port outputs data for parameter setting.

### (Supplementary Note 10)

A reconfigurable circuit comprising:

a first crossbar memory including the logical operation circuit according to any one of supplementary notes 1 to 5;

a second crossbar memory including the logical operation circuit according to any one of supplementary notes 1 to 5; and

a multiplexer that selects an output from a first output port of the first crossbar memory, and outputs the output to a second output port of the second crossbar memory.

### (Supplementary Note 11)

An integrated circuit that comprises a plurality of the logical operation circuits according to any one of supplementary notes 1 to 5, a plurality of the lookup tables according to any one of supplementary notes 6 to 9, or a plurality of the reconfigurable circuits according to supplementary note 10, and is configured by connecting the above to one another.

### (Supplementary Note 12)

An integrated circuit comprising:

the logical operation circuit according to any one of supplementary notes 1 to 5, the lookup table according to any one of supplementary notes 6 to 9, or the reconfigurable circuit according to supplementary note 10 or 11; and

an arithmetic circuit that is not reconfigurable but enables a signal processing function, wherein

the logical operation circuit, the lookup table, or the reconfigurable circuit, and an arithmetic circuit that enables the signal processing function transmit and receive a signal to and from each other via a signal switching unit.

### (Supplementary Note 13)

The logical operation circuit according to any one of supplementary notes 1 to 5, wherein

a complementary element included in the plurality of first switch cells and the plurality of second switch cells is a first resistance change element and a second resistance change element of a bipolar type, and

the first resistance change element and the second resistance change element are disposed in such a way that resistance change polarities face each other.

### (Supplementary Note 14)

The logical operation circuit according to supplementary note 13, wherein

the first resistance change element and the second resistance change element are an atom transfer-type element using an ion conductive layer.

The present invention has been described above by taking the above-described example embodiments as exemplary examples. However, the present invention is not limited to the above-described example embodiment. In other words, various aspects that can be understood by those skilled in the art can be applied to the present invention within the scope of the present invention.

This application is based upon and claims the benefit of priority from Japanese patent application No. 2017-182658, filed on Sep. 22, 2017, the disclosure of which is incorporated herein in its entirety by reference.

### REFERENCE SIGNS LIST

11a, 11b, 11d, 11e, 11g, 11h Switch cell
171a to 171c, 172a to 172c, 181a, 181b, 182a, 182b Control transistor
30, 40a, 40b, 40c, 50a, 50b Crossbar switch circuit
31, 31a, 31b, 31c, 31d, 41a, 41b, 51a Multiplexer
32 Lookup table
52 CMOS switch
60, 70 Integrated circuit
61, 71 Reconfigurable circuit
61a Routing block
61b Logic block
72 Arithmetic circuit
73 Signal switching unit

What is claimed is:

1. A logical operation circuit that comprises a plurality of first switch cells each including a resistance change element and a plurality of second switch cells each including a resistance change element, the logical operation circuit comprising:
a first output port and a second output port;
a plurality of first wires disposed along a first direction and connected to the first output port;
a plurality of second wires disposed along the first direction and connected to the second output port;
a plurality of first writing control lines disposed along the first wire and the second wire;
a plurality of third wires disposed along a second direction;
a plurality of second writing control lines disposed along the third wire;
the plurality of first switch cells that are disposed at a place where the first wire and the third wire intersect each other, have one of diffusion layers being connected to the first writing control line, and another diffusion layer being connected to the second writing control line, and switch an electrical connection between the first wire and the third wire;
the plurality of second switch cells that are disposed at a place where the second wire and the third wire intersect each other, have one of diffusion layers being connected to the first writing control line, and another diffusion layer being connected to the second writing control line, and switch an electrical connection between the second wire and the third wire;
a first control transistor that is connected to the first wire, and switches an electrical connection between a first power source line supplying power to the first wire and the first wire;
a second control transistor that is connected to the second wire, and switches an electrical connection between the first power source line supplying power to the second wire and the second wire;
a third control transistor that is connected to the first writing control line, and switches an electrical connection between a second power source line supplying power to the first writing control line and the first writing control line; and
a fourth control transistor that is connected to the third wire, and switches an electrical connection between a third power source line supplying power to the third wire and the third wire.

2. The logical operation circuit according to claim 1, wherein
a plurality of the first control transistors are provided according to a number of the plurality of first wires, and
a gate of the plurality of first control transistors is connected in a shared manner.

3. The logical operation circuit according to claim 1, wherein
a plurality of the second control transistors are provided according to a number of the plurality of second wires, and
a gate of the plurality of second control transistors is connected in a shared manner.

4. The logical operation circuit according to claim 1, wherein,
among a plurality of second writing control lines, a gate of a third control transistor connected to a second writing control line connected to the plurality of first switch cells and a gate of a fourth control transistor connected to a third wire connected to the plurality of first switch cells are connected to a gate of the plurality of first control transistors in a shared manner.

5. The logical operation circuit according to claim 1, wherein,
among a plurality of second writing control lines, a gate of a third control transistor connected to a second writing control line connected to the plurality of second switch cells and a gate of a fourth control transistor connected to a third wire connected to the plurality of second switch cells are connected to a gate of the plurality of second control transistors in a shared manner.

6. A lookup table comprising:
a crossbar memory including the logical operation circuit according to claim 1; and
a multiplexer that selects and outputs an output from the first output port or the second output port of the crossbar memory.

7. The lookup table comprising:
a crossbar memory including the logical operation circuit according to claim 1;
a multiplexer that selects and outputs an output from the first output port or the second output port of the crossbar memory;
a plurality of the logical operation circuits according to claim 1;
a plurality of switches of a first conductive-type transistor being a plurality of switches that select an output from the first output port of one of the logical operation circuits;
a plurality of switches of a second conductive-type transistor being a plurality of switches that selects an output from the second output port of another of the logical operation circuits; and
an output node derived from a switch of an output stage of the plurality of switches of the first conductive-type transistor and a switch of an output stage of the plurality of switches of the second conductive-type transistor.

8. The lookup table according to claim 7, further comprising:
a switch of a first conductive-type transistor inserted between a switch of an output stage of the plurality of switches of the first conductive-type transistor and the output node; and
a switch of a second conductive-type transistor inserted between a switch of an output stage of the plurality of switches of the second conductive-type transistor and the output node.

9. The lookup table according to claim 6, wherein
the first output port or the second output port on a side that is not selected by the multiplexer that selects an output from the first output port or the second output port among the first output port and the second output port outputs data for parameter setting.

10. A reconfigurable circuit comprising:
a first crossbar memory including the logical operation circuit according to claim 1;
a second crossbar memory including the logical operation circuit according to claim 1; and
a multiplexer that selects an output from a first output port of the first crossbar memory, and outputs the output to a second output port of the second crossbar memory.

11. An integrated circuit that comprises a plurality of the logical operation circuits according to claim 1, and is configured by connecting the above to one another.

12. An integrated circuit comprising:
the logical operation circuit according to claim 1; and
an arithmetic circuit that is not reconfigurable but enables a signal processing function, wherein
the logical operation circuit, and an arithmetic circuit that enables the signal processing function transmit and receive a signal to and from each other via a signal switching unit.

13. The logical operation circuit according to claim 1, wherein
a complementary element included in the plurality of first switch cells and the plurality of second switch cells is a first resistance change element and a second resistance change element of a bipolar type, and
the first resistance change element and the second resistance change element are disposed in such a way that resistance change polarities face each other.

14. The logical operation circuit according to claim 13, wherein
the first resistance change element and the second resistance change element are an atom transfer-type element using an ion conductive layer.

15. An integrated circuit that comprises a plurality of the lookup tables according to claim 6, and is configured by connecting the above to one another.

16. An integrated circuit that comprises a plurality of the reconfigurable circuits according to claim 10, and is configured by connecting the above to one another.

17. An integrated circuit comprising:
the lookup table according to claim 6; and
an arithmetic circuit that is not reconfigurable but enables a signal processing function, wherein
the lookup table, and an arithmetic circuit that enables the signal processing function transmit and receive a signal to and from each other via a signal switching unit.

18. An integrated circuit comprising:
the reconfigurable circuit according to claim 10; and
an arithmetic circuit that is not reconfigurable but enables a signal processing function, wherein
the reconfigurable circuit, and an arithmetic circuit that enables the signal processing function transmit and receive a signal to and from each other via a signal switching unit.
